(19) United States
(12) Patent Application Publication
(10) Pub. No.: US 2007/0181927 A1
(43) Pub. Date: Aug. 9, 2007

(54) Charge balance insulated gate bipolar transistor

(76) Inventors: Joseph Andrew Yedinak, Mountain Top, PA (US); Kwang Hoon Oh, Seoul (KR); Chongman Yun, Seoul-Si (KR); Jae Gil Lee, Puchon-Si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/408,812

(22) Filed: Apr. 21, 2006

Related U.S. Application Data
(60) Provisional application No. 60/765,261, filed on Feb. 3, 2006.

(51) Int. Cl. H01L 29/94

(52) U.S. Cl. 257/302

(57) ABSTRACT

An IGBT includes a first silicon region over a collector region, and a plurality of pillars of first and second conductivity types arranged in an alternating manner over the first silicon region. The IGBT further includes a plurality of well regions each extending over and being in electrical contact with one of the pillars of the first conductivity type, and a plurality of gate electrodes each extending over a portion of a corresponding well region. The physical dimensions of each of the first and second conductivity type pillars and the doping concentration of charge carriers in each of the first and second conductivity type pillars are selected so as to create a charge imbalance between a net charge in each pillar of first conductivity and a net charge in its adjacent pillar of the second conductivity type.

### CROSS-REFERENCES TO RELATED APPLICATIONS

This application claims the benefit of US Provisional Application No. 60/765,261, filed Feb. 3, 2006, which disclosure is incorporated herein by reference in its entirety for all purposes.

### BACKGROUND OF THE INVENTION

The present invention relates to semiconductor power devices, and more particularly to structures and methods for forming insulated gate bipolar transistors (IGBT) with charge balance structures.

IGBT is one of a number of commercially available semiconductor power devices. FIG. 1 shows a cross section view of a conventional IGBT. A highly doped P-type collector region 104 is electrically connected to a collector electrode 102. An N-type drift region 106 is formed over collector region 104. A highly doped P-type well region 108 is formed in drift region 106, and a highly doped N-type source region 110 is formed in P-type well region 108. Both well region 108 and source region 110 are electrically connected to an emitter electrode 112. A planar gate 114 extends over an upper surface of drift region 106 and a channel region 113 in well region 108, and overlaps the source region 110. Gate 114 is insulated from the underlying regions by a gate dielectric layer 116.

Optimization of the various competing performance parameters of conventional IGBTs such as that in FIG. 1 is limited by a number of factors including the required high doping of the P-type collector region and a required finite thickness for the N-type drift region. These factors limit various trade-off performance improvements. Thus, there is a need for improved IGBTs wherein the trade-off performance parameters can be better controlled enabling improving the same.

### BRIEF SUMMARY OF THE INVENTION

In accordance with an embodiment of the invention, an insulated gate bipolar transistor (IGBT) includes a collector region of a first conductivity type, and a first silicon region of a second conductivity type extending over the collector region. A plurality of pillars of first and second conductivity types are arranged in an alternating manner over the first silicon region. A bottom surface of each pillar of first conductivity type is vertically spaced from a top surface of the collector region. The IGBT further includes a plurality of well regions of the first conductivity type each extending over and being in electrical contact with one of the pillars of the first conductivity type, and a plurality of gate electrodes each extending over a portion of a corresponding well region. Each gate electrode is insulated from its underlying regions by a gate dielectric layer. The physical dimensions of each of the first and second conductivity type pillars and the doping concentration of charge carriers in each of the first and second conductivity type pillars are selected so as to create a charge imbalance between a net charge in each pillar of first conductivity and a net charge in its adjacent pillar of the second conductivity type.

In accordance with another embodiment of the invention, an IGBT includes a collector region of a first conductivity type and a first silicon region of a second conductivity type extending over the collector region. A plurality of pillars of first and second conductivity types are arranged in an alternating manner over the first silicon region. A bottom surface of each pillar of first conductivity type is vertically spaced from a top surface of the collector region. A well region of the first conductivity type extends over and is in electrical contact with the plurality of pillars of first and second conductivity types. The IGBT further includes a plurality of gate trenches each extending through the well region and terminating within one of the pillars of second conductivity type, with each gate trench including a gate electrode therein. The physical dimensions of each of the first and second conductivity type pillars and doping concentration of charge carriers in each of the first and second conductivity type pillars are selected so as to create a charge imbalance between a net charge in each pillar of first conductivity and a net charge in its adjacent pillar of the second conductivity type.

In accordance with yet another embodiment of the invention, an IGBT is formed as follows. An epitaxial layer is formed over a collector region of a first conductivity type, with the epitaxial layer being of a second conductivity type. A first plurality of pillars of the first conductivity type are formed in the epitaxial layer such that those portions of the epitaxial layer separating the first plurality of pillars from one another form second plurality of pillars thus forming pillars of alternating conductivity type, and a bottom surface of each of the first plurality of pillars is spaced from a top surface of the collector region. A plurality of well regions of the first conductivity type are formed in the epitaxial layer such that each well region extends over and is in electrical contact with one of the first plurality of pillars. A plurality of gate electrodes is formed, each extending over a portion of a corresponding well region and being insulated from its underlying regions by a gate dielectric layer. The physical dimensions of each of the first and second conductivity type pillars and doping concentration of charge carriers in each of the first and second conductivity type pillars are selected so as to create a charge imbalance between a net charge in each pillar of first plurality of pillars and a net charge in its adjacent pillar of the second plurality of pillars.

In accordance with another embodiment of the invention, an IGBT is formed as follows. An epitaxial layer is formed over a collector region of a first conductivity type, wherein the first silicon region is of a second conductivity type. A first plurality of pillars of the first conductivity type are formed in the epitaxial layer such that those portions of the epitaxial layer separating the first plurality of pillars from one another form second plurality of pillars thus forming pillars of alternating conductivity type, and a bottom surface of each of the first plurality of pillars is spaced from a top surface of the collector region. A well region of the first conductivity type is formed in the epitaxial layer such that the well region extends over and is in electrical contact with the first and second plurality of pillars. A plurality of gate trenches is formed, each extending through the well region and terminating within one of the second plurality of pillars. A gate electrode is then formed in each gate trench. The physical dimensions of each of the first and second conductivity type pillars and doping concentration of charge carriers in each of the first and second conductivity type pillars are selected so as to create a charge imbalance between a net charge in each pillar of first plurality of pillars and a net charge in its adjacent pillar of the second plurality of pillars.

In accordance with another embodiment of the invention, an IGBT is formed as follows. Dopants of a first conductivity type are implanted along a back side of a substrate of a first conductivity type to form a collector region of the first conductivity type in the substrate. A first plurality of pillars of the first conductivity type are formed in the substrate such that those portions of the substrate separating the first plurality of pillars from one another form second plurality of pillars thus forming pillars of alternating conductivity type, and a bottom surface of each of the first plurality of pillars is spaced from a top surface of the collector region. The physical dimensions of each of the first and second conductivity type pillars and doping concentration of charge carriers in each of the first and second conductivity type pillars are selected so as to create a charge imbalance between a net charge in each pillar of first plurality of pillars and a net charge in its adjacent pillar of the second plurality of pillars.

In accordance with another embodiment of the invention, an IGBT is formed as follows. An epitaxial layer is formed over a substrate. The substrate is completely removed to expose a backside of the epitaxial layer. Dopants of a first conductivity type are implanted along the exposed back side of the epitaxial layer to form a collector region of the first conductivity type in the epitaxial layer. A first plurality of pillars of the first conductivity type are formed in the epitaxial layer such that those portions of the epitaxial layer separating the first plurality of pillars from one another form second plurality of pillars thus forming pillars of alternating conductivity type, and a bottom surface of each of the first plurality of pillars being spaced from a top surface of the collector region. The physical dimensions of each of the first and second conductivity type pillars and doping concentration of charge carriers in each of the first and second conductivity type pillars are selected so as to create a charge imbalance between a net charge in each pillar of first plurality of pillars and a net charge in its adjacent pillar of the second plurality of pillars.

In accordance with another embodiment of the invention, an IGBT is formed as follows. An epitaxial layer is formed over a substrate. The substrate is thinned down through its backside, and dopants of a first conductivity type are implanted along a back side of the thinned down substrate to form a collector region of the first conductivity type contained within the thinned down substrate. The substrate and the epitaxial layer are of a second conductivity type. A first plurality of pillars of the first conductivity type are formed in the epitaxial layer such that those portions of the epitaxial layer separating the first plurality of pillars from one another form second plurality of pillars thus forming pillars of alternating conductivity type, a bottom surface of each of the first plurality of pillars being spaced from a top surface of the collector region. The physical dimensions of each of the first and second conductivity type pillars and doping concentration of charge carriers in each of the first and second conductivity type pillars are selected so as to create a charge imbalance between a net charge in each pillar of first plurality of pillars and a net charge in its adjacent pillar of the second plurality of pillars

A better understanding of the nature and advantages of the present invention can be gained from the following detailed description and the accompanying drawings.

### BRIEF DESCRIPTION OF THE DRAWINGS

FIG. 1 shows a cross section view of a conventional planar gate IGBT;

FIG. 2 shows a cross section view of a planar gate superjunction IGBT in accordance with an embodiment of the invention;

FIG. 3 shows simulation results wherein the hole carrier concentration is plotted versus distance from the surface of the silicon for the superjunction IGBT in FIG. 2, in accordance with an embodiment of the invention;

FIG. 4 shows simulation results wherein the turn-off energy (Eoff) is plotted versus collector to emitter on-state voltage Vce(sat) for a conventional IGBT and two cases of superjunction IGBTs having similar structures to that in FIG. 2;

FIGS. 5-18 are simulation results showing the sensitivity of various parameters to charge imbalance as well as various trade-off performances for exemplary embodiments of the inventions;

FIGS. 19-22 show cross section views and corresponding doping profiles of various superjunction IGBTs in accordance with embodiments of the invention;

FIG. 23 shows a cross section view of a trench gate superjunction IGBT in accordance with an embodiment of the invention;

FIG. 24 shows a simplified top layout view for a concentric superjunction IGBT design in accordance with an embodiment of the invention; and

FIG. 25 shows a simplified top layout view for a stripe superjunction IGBT design in accordance with an embodiment of the invention.

### DETAILED DESCRIPTION OF THE INVENTION

FIG. 2 is a cross section view of an improved superjunction IGBT which allows various competing performance parameters to be improved, in accordance with an embodiment of the invention. A highly doped P-type collector region 204 is electrically connected to a collector electrode 202. A N-type field stop layer (FSL) 205 extends over collector region 204, and an N-type region 206a extends over FSL 205. A charge balance region comprising alternating P-pillars 207 and N-pillars 206b extends over N-type region 206a. In an alternate embodiment, region 207 of the charge balance region comprises a P-type silicon liner extending along the vertical boundaries and the bottom boundary of region 207 with the remainder of region 207 being N-type or intrinsic silicon.

A highly doped P-type well region 208 extends over P-pillars 207, and a highly doped N-type source region 210 is formed in well region 208. Both well region 208 and source region 210 are electrically connected to an emitter electrode 212. A planar gate 214 extends over an upper surface of N-type region 206c and a channel region 213 in well region 208, and overlaps source region 210. Gate 214 is insulated from the underlying silicon regions by a gate dielectric layer 216.

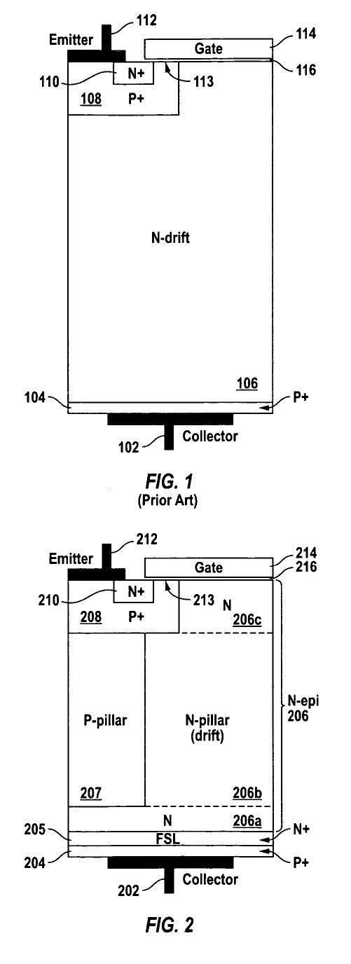

In the conventional IGBT structure of FIG. 1, in order to sustain a high blocking voltage the thickness of drift region 106 is made large. Under high reverse bias voltages, the electric field distribution in drift region 106 is triangular and the peak field occurs at the junction between well region 108 and drift region 106. In FIG. 2, by introducing the charge balance structure comprising the alternating P-pillars 207 and N-pillars 206b, a trapezoidal electric field distribution is obtained and the peak electric field is suppressed. A much higher break down voltage for the same doping concentration of the drift layer is thus achieved. Alternatively, for the same breakdown voltage, the doping concentration of the drift region can be increased and/or the thickness of the drift region can be reduced, thus improving the IGBT collector to emitter on-state voltage Vce(sat).

Furthermore, P-type pillars 207 advantageously serve as a collector for the stored hole carriers thus improving the transistor switching speed. Moreover, the charge-balance structure distributes the hole and electron current components of the IGBT between the P-pillars and N-pillars, respectively. This improves the latch-up immunity of the transistor, and also helps distribute heat more uniformly in the silicon.

Additionally, field stop layer 205 serves to prevent the depletion layer from spreading to collector region 204. In an alternate embodiment, N-type field stop layer 205 is eliminated such that N-type region 206a is in direct contact with P-type collector region 204. In this alternate embodiment, N-type region 206a serves as a buffer layer, and the doping concentration and/or the thickness of this buffer layer is adjusted so as to prevent the depletion layer from spreading to collector region 204.

The superjunction IGBT in FIG. 2 may be manufactured in a number of ways. In one embodiment, the P-pillars are formed by forming deep trenches an epitaxial layer 206, and then filling the trenches with P-type silicon material using such techniques as SEG. Alternatively, the P-pillars may be formed using ultra high energy implantation, or multi-implantations at various energies into epitaxial layer 206. Other process techniques can also be envisioned by one skilled in the art in view of this disclosure. In an alternate process embodiment, after forming deep trenches, the trench sidewalls and bottom are lined with P-type silicon using conventional techniques, followed by filling the trenches with N-type or intrinsic silicon.

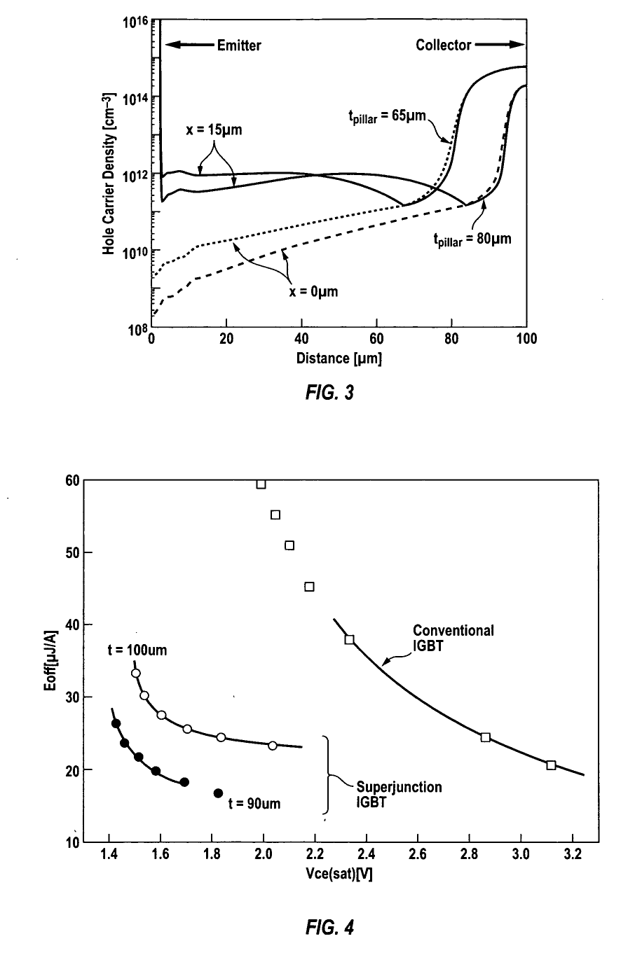

FIG. 3 shows simulation results wherein the hole carrier concentration is plotted versus distance from the surface of the silicon. For the same wafer thickness of about 100 μm, the hole carrier density along the center of the P-pillar (marked in FIG. 3 as x=15 μm) and along the center of the N-pillar (marked in FIG. 3 as x=0 μm) are plotted for two cases of P-pillar depth of 80 μm (marked in FIG. 3 as tₚᵢₗₗₐᵣ=80 μm) and 65 μm (marked in FIG. 3 as tₚᵢₗₗₐᵣ=65 μm). It can be seen that a significant majority of the hole carriers flow through the P-pillar rather than the N-pillar.

FIG. 4 shows simulation results wherein the turn-off energy (Eoff) is plotted versus collector to emitter on-state voltage Vce(sat) for a conventional IGBT and two cases of superjunction IGBT's (with structures similar to that in FIG. 2) with wafer thicknesses of 90 μm and 100 μm. As can be seen, the Vce(sat)/Eoff trade-off is significantly improved in the superjunction IGBTs compared to the conventional IGBT.

To obtain the breakdown voltage improvements associated with the alternating pillar structure, both the N-pillars and P-pillar need to be fully depleted. In the depletion region, space charge neutrality condition needs to be maintained, hence requiring charge balance between negative charges in P-type pillars and positive charges in the N-type pillars (drift region). This requires careful engineering of the doping and physical characteristics of the N-type and P-type pillars. However, as is described more fully below, the superjunction IGBT in accordance with the present invention is designed so as to improve a number of trade-off performances by introducing a predetermined amount of charge imbalance between adjacent N and P Pillars rather than perfect charge balance.

As will be seen, a charge imbalance in the range of 5-20% in favor of higher charge in the P-pillars leads to improvements in various trade-off performances. In one embodiment, a thinner epitaxial layer 206 with doping concentration which results in a net charge in the N-pillars in the range of 5×10¹⁰a/cm³ to 1×10¹²a/cm³ is used, while the doping concentration of the P-pillars is set such that the net charge in the P-pillars is greater by about 5-20% than that of the N-pillars. In a stripe design, the net charge in each of the N and P pillars can roughly be approximated by the product of the doping concentration in the pillar and the width of the pillar (assuming the stripes of N and P pillars have the same depth and length).

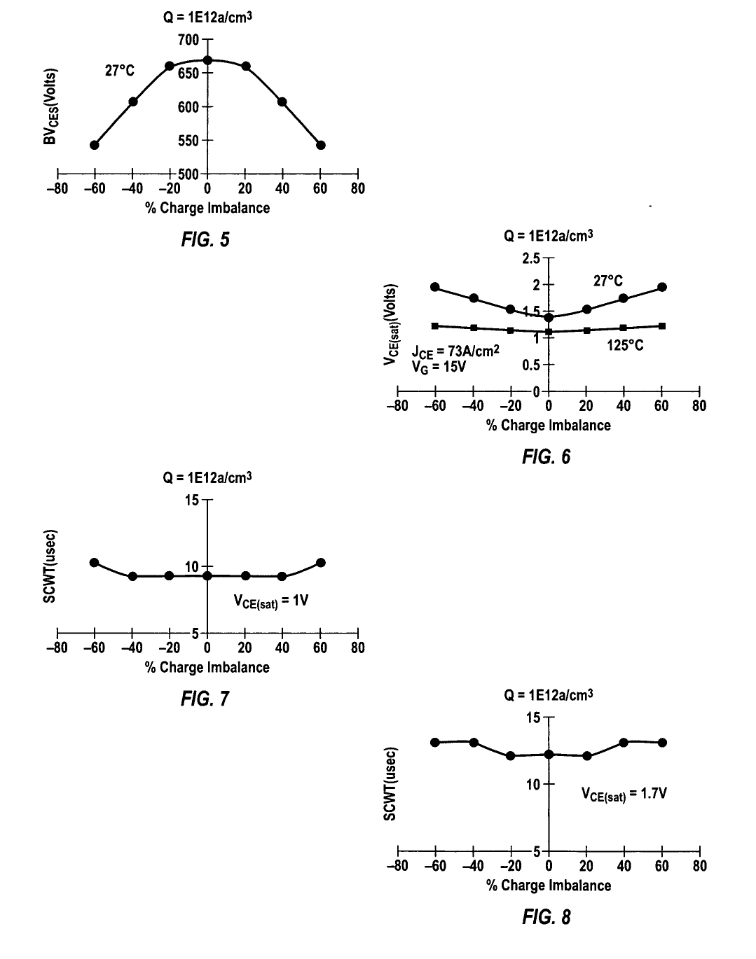

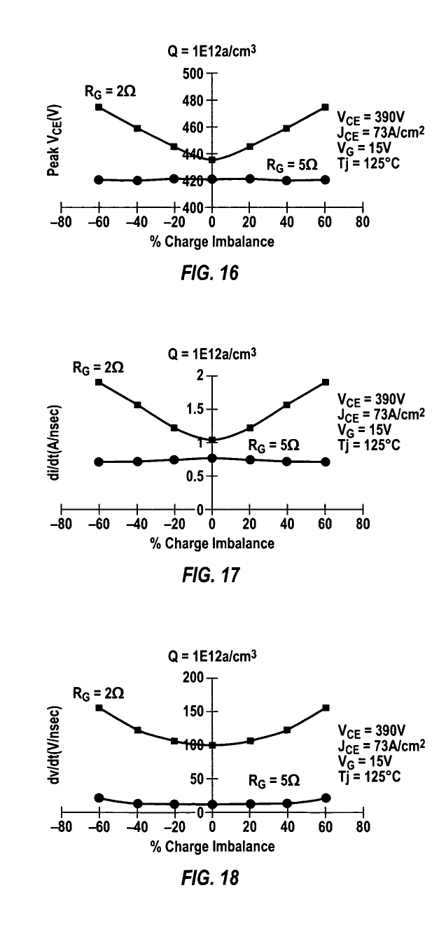

By optimizing the net charge in the alternate pillars and the superjunction structure, various trade-off performances can be controlled and improved as illustrated by the simulation results shown in FIGS. 5-18. FIGS. 5 and 6 show simulation results wherein the sensitivity of BVces and Vce(sat) to charge imbalance are respectively shown at various temperatures for an N-pillar charge Q of 1×10¹²a/cm³. The charge imbalance indicated along the horizontal axes in FIGS. 5 and 6 is obtained by increasing or decreasing the amount of charge in the P-pillars relative to that of N-pillars. In accordance with the invention, the N and P pillars are modulated so that a lower charge (e.g., less than or equal to 1×10¹²a/cm³) can be used, dramatically reducing the sensitivity of Vce(sat) and BVces to charge imbalance.

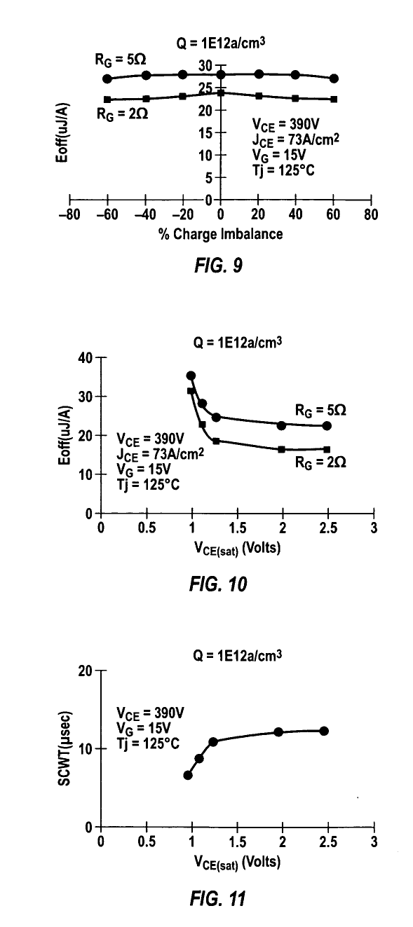

FIGS. 7 and 8 show simulation results wherein the sensitivity of the short circuit withstand time SCWT to charge imbalance is shown for an N-pillar charge of 1×10¹²a/cm³ and Vce(sat) of 1V and 1.7V, respectively. FIG. 9 shows simulation results wherein the sensitivity of turn-off energy Eoff is shown for the same N-pillar charge of 1×10¹²a/cm³. FIGS. 10 and 11 show the Vce(sat) versus Eoff trade-off and Vce(sat) versus SCWT trade-off for the same N-pillar and P-pillar charge of 1×10¹²a/cm³ (i.e., a charge balanced structure). As can be seen from these figures, a 20 μJ/A Eoff at 125° C. with VCE(sat) of less than 1.2V at 125° C. and SCWT greater than 10 μsec that is immune to charge imbalance can be achieved.

The SCWT performance improves because P-pillars 207 act as sinks for the hole current. Therefore, the hole current tends to flow up P-pillars 207 rather than under the source region 110 as is in the conventional IGBT in FIG. 1. This makes the superjunction IGBT in FIG. 2 impervious to NPN latch-up during SCWT. This current flow also results in self heating during SCWT that is more uniform and not localized as in the conventional IGBT in FIG. 1. This further allows the superjunction IGBT in FIG. 2 to be operated with higher PNP gain and reduces the failure due to turning on the PNP with thermally generated leakage current at the forward junction. This has been a shortcoming of conventional IGBTs because as the temperature rises in the drift region, the minority carrier lifetime increases because there is a positive temperature coefficient of minority carrier lifetime. The thermally generated leakage from the concentrated high temperature at the forward junction and the thermally increasing PNP gain cause the PNP to turn-on sooner.

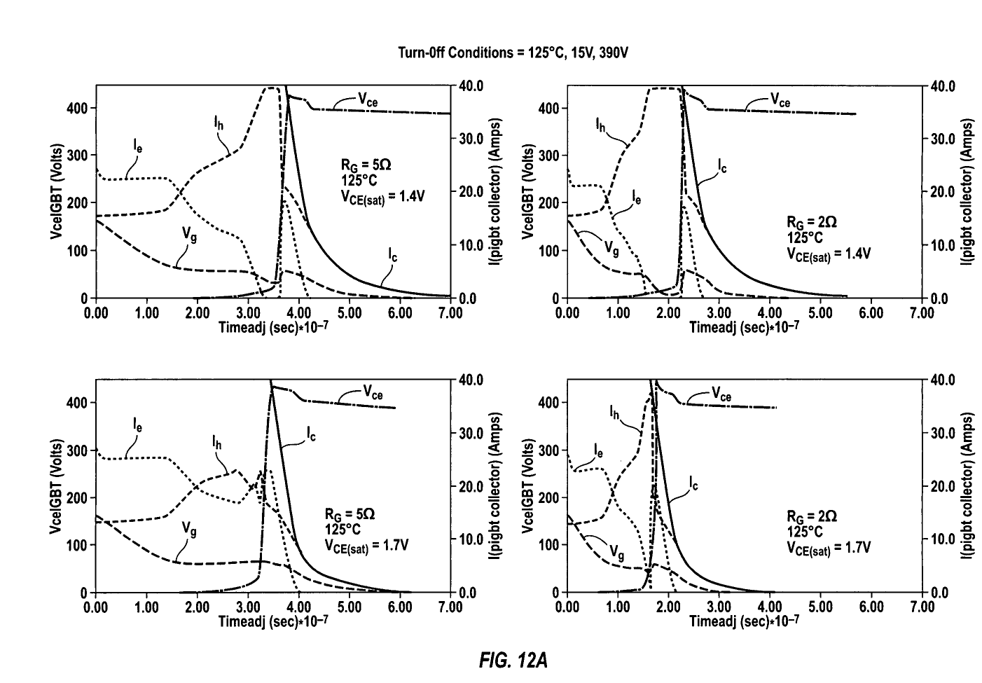

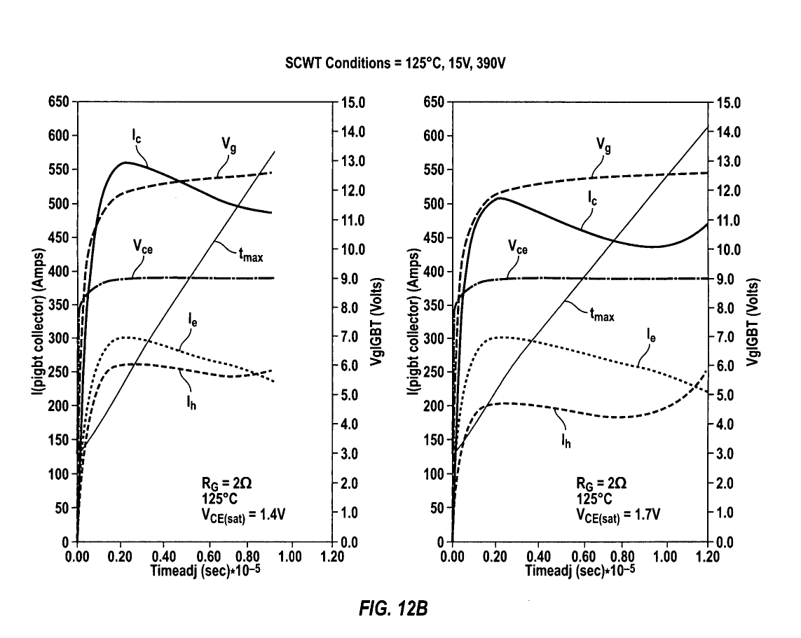

Another important feature of the superjunction IGBT in FIG. 2 is it facilitates forming a quick punch through (QPT) like turn-off which has turn-off di/dt that is gate controlled by changing gate resistance Rg. The QPT refers to the tailoring of the cell (e.g., the gate structure and the PNP gain) so that the effective gate bias is above the threshold voltage Vth of the IGBT when the current starts to fall as depicted by the timing diagrams in FIGS. 12A and 12B (which are simulation results for a superjunction IGBT). The QPT is more fully described in the commonly assigned U.S. Pat. No. 6,831,329 issued on Dec. 14, 2004, which disclosure is incorporated herein by reference in its entirety.

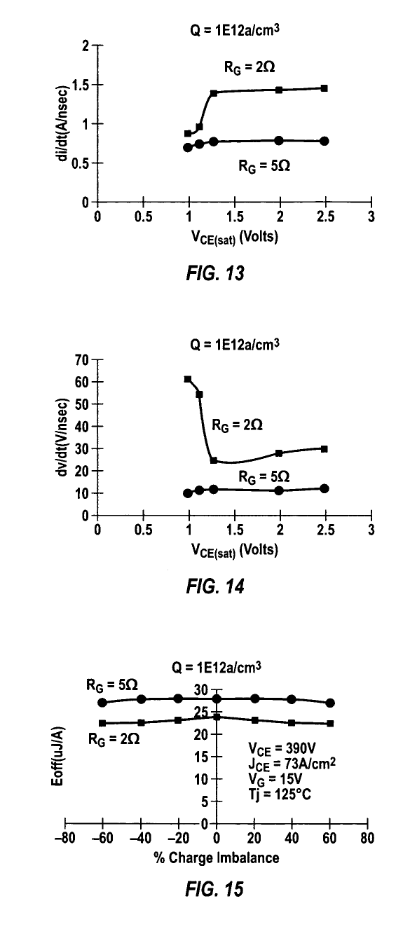

FIGS. 13 and 14 respectively show the Vce(sat) versus di/dt trade-off and Vce(sat) versus dv/dt trade-off for the same N-pillar charge and P-pillar charge of 1×10¹²a/cm³ for two Rg values. FIGS. 15, 16, 17 and 18 respectively show the sensitivity of Eoff, Peak Vce, di/dt and dv/dt to charge imbalance for two Rg values with the N-pillar charge equal to 1×10¹²a/cm³. As can be seen from FIGS. 10 and 13, slowing down the turn-off di/dt increases Eoff, but this provides the flexibility to trade-off Eoff for EMI performance. The dv/dt of the superjunction IGBT is high due to the fast 3-D sweep out of minority carriers. The superjunction IGBT with QPT has minimal turn-off losses during the voltage rise. The dv/dt can also be controlled to some extent with Rg as shown in FIG. 14.

Most of the turn-off losses in the conventional IGBT result from the slow sweep out of the injected carriers during the voltage rise and the minority carrier recombination of the carriers in the remaining un-depleted drift and/or buffer region after the voltage reaches the bus voltage. Because the current fall di/dt is controlled by the gate discharge and is much slower than a conventional IGBT, Eoff is almost completely due to the current fall. In essence, most of the turn-off losses of the superjunction IGBT are in the current fall which can be controlled by adjusting the di/dt with Rg.

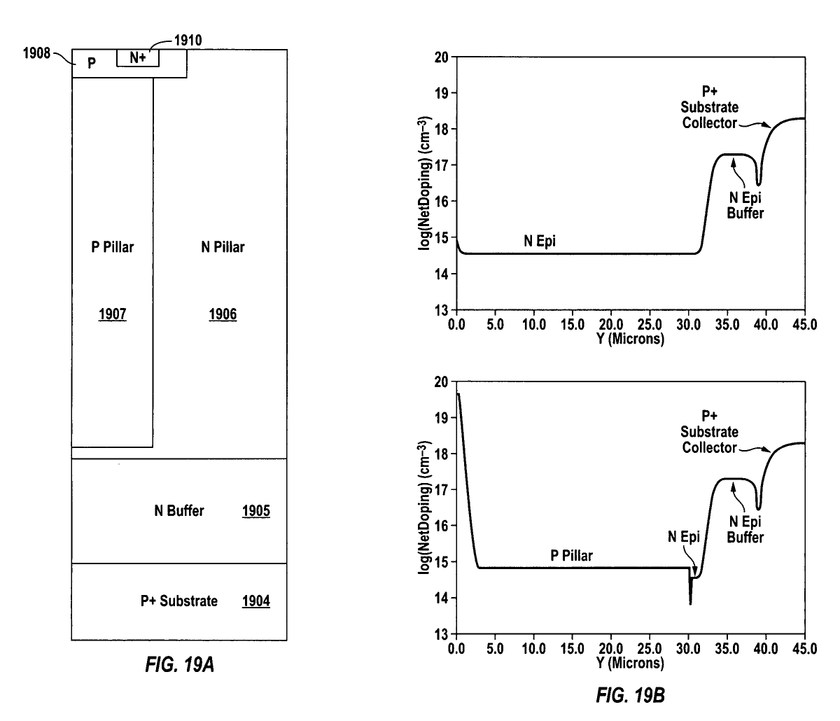

FIGS. 19-22 show cross section views and corresponding doping profiles of various superjunction IGBTs in accordance with embodiments of the invention. FIG. 19A shows an embodiment wherein the starting wafer is a P+ substrate 1904 over which an N-epi buffer layer 1905 is formed. An upper N-epi layer 1906 of lower doping concentration than buffer layer 1905 is then formed over buffer layer 1905. The remaining regions and layers are formed using one of a number of know techniques. For example, P-pillars 1907 can be formed by implanting (using high energy) P-type dopants into the upper N-epi layer 1906, or by forming a trench in the upper N-epi layer 1906 and then filling the trench with P-type silicon. In yet another embodiment, instead of the upper N-epi layer 1906, multi-layers of n-epi are formed and after forming each n-epi layer, a P-type implant is carried out to form a corresponding portion of P-pillar 1907. Body region 1908 and source region 1910 are formed using known techniques. FIG. 19B shows exemplary doping concentrations along a vertical line through the center of the N-pillar (the upper diagram) and along a vertical line through the center of the P-pillar (the lower diagram) of the structure in FIG. 19A.

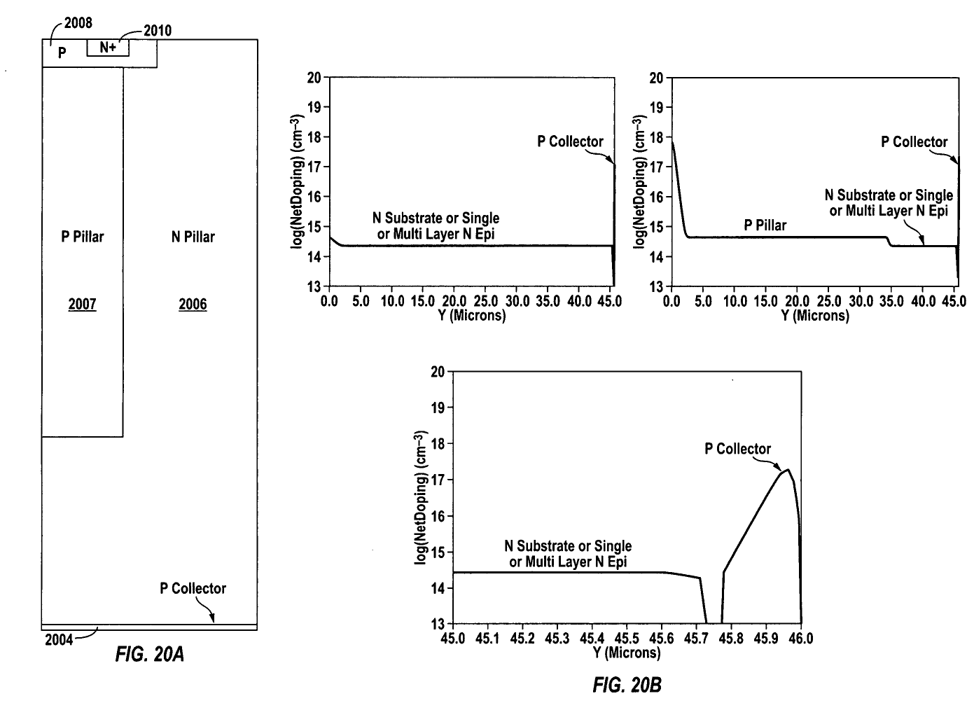

In FIG. 20A, one or multiple N-epi layers, depicted by region 2006, are formed on a substrate and then the substrate is completely removed with the one or multiple epi layers remaining. P-type dopants are implanted into the backside to form collector region 2004. In another embodiment, an N-type substrate with no N-epi layers is used, and the collector region is formed by implanting dopants into the back side of substrate. P-pillar 2007, body region 2008, and source region 2010 are formed using any one of a number of techniques as described with reference to FIGS. 19A. FIG. 20B shows exemplary doping concentrations along a vertical line through the center of the N-pillar (the upper left diagram) and along a vertical line through the center of the P-pillar (the upper right diagram). The lower diagram in FIG. 20B shows an expanded view of the doping profile in the transition region from the n-type substrate or epi layer(s) to and through collector region 2004.

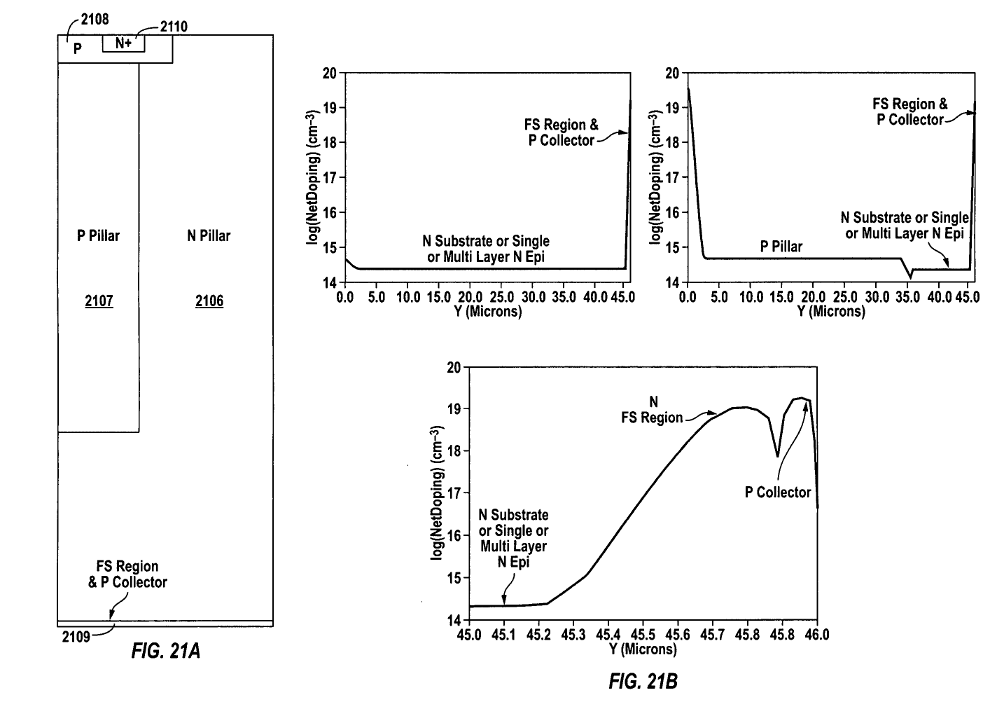

FIG. 21A is a cross section view which is similar to that in FIG. 20A except that an N-type field stop region is incorporated into the structure. In one embodiment, one or multiple N-epi layers are formed on a substrate and then the substrate is completely removed with the one or multiple epi layers remaining. N-type dopants are then implanted into the back side to form the N-type field stop region, followed by P-type dopant implant into the backside to form the collector region within the field stop region. In another embodiment, an N-type substrate with no N-epi layers is used. P-pillar 2107, body region 2108, and source region 2110 are formed using any one of a number of techniques as described with reference to FIGS. 19A. FIG. 21B shows exemplary doping concentrations along a vertical line through the center of the N-pillar (the upper left diagram) and along a vertical line through the center of the P-pillar (the upper right diagram). The lower diagram in FIG. 21B shows an expanded view of the doping profile through the field stop and Collector regions.

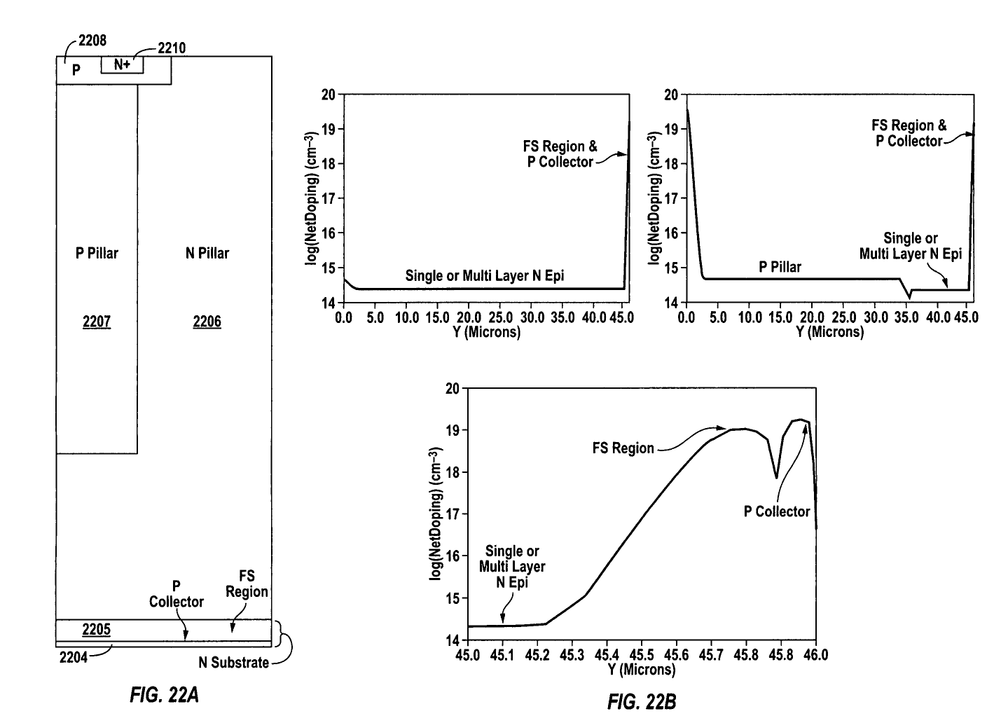

In FIG. 22A, an N-epi layer (or multi N-epi layers) depicted by region 2206 is formed over an n-type substrate, and a predetermined thickness of the substrate is removed on the back side such that a thinner substrate layer of the desired thickness remains. The substrate has a lower resistivity than the N-epi layer. The collector region is then formed by implanting P-type dopants into the backside, with the remaining portion of the substrate, in effect, forming a field stop region. P-pillar 2207, body region 2208, and source region 2210 are formed using any one of a number of techniques as described with reference to FIGS. 19A. FIG. 22B shows exemplary doping concentrations along a vertical line through the center of the N-pillar (the upper left diagram) and along a vertical line through the center of the P-pillar (the upper right diagram). The lower diagram in FIG. 22B shows an expanded view of the doping profile through the field stop and collector regions.

In another embodiment of the invention, the doping concentration in the P-pillars is graded from a higher doping concentration along the top of the P-pillars to a lower doping concentration along their bottom, and the doping concentration in the N-pillars is substantially uniform. In yet another embodiment, the doping concentration in the N-pillars is graded from a higher doping concentration along the bottom of the N-pillars to a lower doping concentration along their top, and the doping concentration in the P-pillars is substantially uniform.

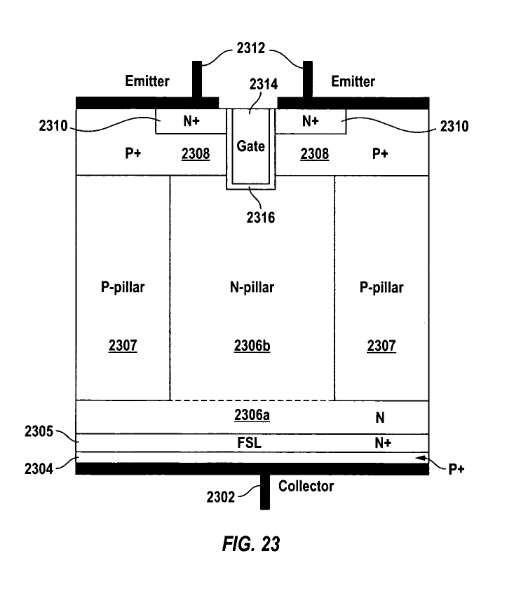

FIG. 23 shows a cross section view of a trench gate superjunction IGBT in accordance with an embodiment of the invention. Except for the gate structure and its surrounding regions, the trench gate IGBT in FIG. 23 is structurally similar to the planar gate IGBT in FIG. 2 and thus many of the same features and advantages described above in connection with the planar gate IGBT in FIG. 2 and its variations and alternate embodiments can be realized with the trench gate IGBT in FIG. 23. In FIG. 23, a highly doped P-type collector region 2304 is electrically connected to a collector electrode 2302. A N-type field stop layer (FSL) 2305 extends over collector region 2304, and an N-type region 2306a extends over FSL 2305. A charge balance region comprising alternating P-pillars 2307 and N-pillars 2306b extends over N-type region 2306a. In an alternate embodiment, region 2307 of the charge balance region comprises a P-type silicon liner extending along the vertical boundaries and the bottom boundary of region 2307 with the remainder of region 2307 being N-type or intrinsic silicon.

A highly doped P-type well region 2308 extends over the charge balance structure, and a gate trench extends through the well region 2308 and terminates in N-pillar 2306b. Highly doped N-type source regions 2310 flank each side of the gate trench in well region 2308. Well region 2308 and source regions 2310 are electrically connected to emitter electrode 2312. A gate dielectric 2316 lines the trench sidewalls, and a gate 2314 (e.g., comprising polysilicon) fills the trench. Gate 2314 may be recessed in the trench with a dielectric cap filling the trench over the recessed gate. An emitter conductor (e.g., comprising metal) may then extend over source regions, body regions and the trench gate. Many of the same considerations discussed above in reference to the planar gate IGBT in FIG. 2 also apply to the trench gate IGBT in FIG. 23.

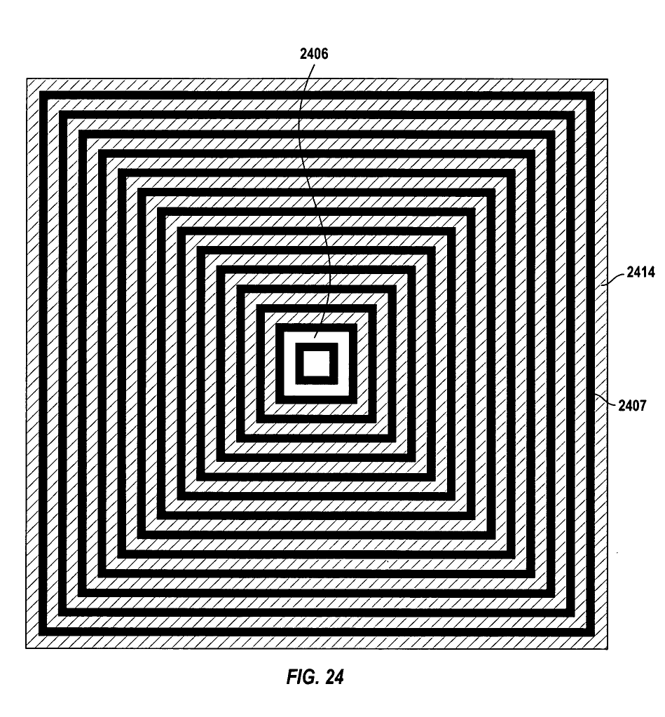

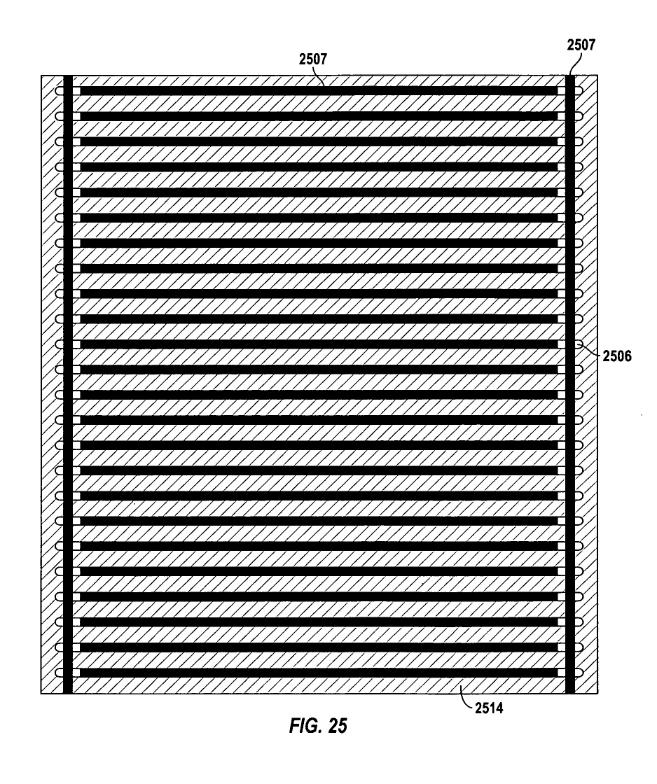

The planar gate IGBT in FIG. 2 and trench gate IGBT in FIG. 23 and their variants may be laid out in a number of different ways. Two exemplary layout designs are shown in FIGS. 24 and 25. FIG. 24 illustrates a concentric pillar design with concentric gates. As shown, progressively larger square-shaped rings of P-pillars 2407 (solid black rings) equally spaced from one another are formed starting from the center of the die. A square-shaped gate ring 2414 (cross hatched ring) is formed between every two adjacent P-pillar rings. As shown, no gate is formed in the region surrounded by the most inner P-pillar ring or in between the first two inner P-pillar rings for charge balance reasons. Source and body regions (not shown) are also ring shaped however, the source regions need to either be discontinuous rings or continuous rings with discontinuous channel regions in order to prevent latch-up.

Gate rings 2414 are shown as not extending over P-pillar rings 2407, however, in an alternate embodiment the gate rings overlap the P-pillar rings. Also, the concentric P-pillar rings 2407 and gate rings 2414 are shown to be square shaped, however they may be rectangular, polygonal, hexagonal, circular, or other geometrical shapes. In one embodiment, stripe-shaped gates extending vertically or horizontally over the concentric P-pillar rings are used instead of concentric gate rings. Such embodiment is advantageous in that the gates are not required to be properly aligned to the P-pillars as in the concentric gate ring design. This embodiment also increases the peak SCWT.

FIG. 25 illustrates a striped pillar design with striped gates. As shown, stripe-shaped P-pillars 2507 (solid black stripes) equally spaced from one another extend across a length of the die, with a stripe-shaped gate 2514 (cross hatched regions) extending between every two adjacent P-pillar stripes. Source and body regions (not shown) are also stripe-shaped. FIG. 25 also shows a portion of the termination region along the right and left side of the die where vertically extending P-pillars 2507 are included. These vertically extending P-pillars are properly spaced from the horizontally extending P-pillars in the active region to maintain charge balance in the transition region between the active and termination regions.

Gate stripes 2514 are shown as not extending over P-pillar stripes 2507 however, in an alternate embodiment the gate stripes overlap the P-pillar stripes. Also, gate stripes 2514 are shown extending in parallel to P-pillars 2507, however, in an alternate embodiment the gate stripes extend perpendicular to the P-pillar strips. Such embodiment is advantageous in that the gates are not required to be properly aligned to the P-pillars as required in the embodiment with the gate and P-pillar stripes extending in parallel. This embodiment also increases the peak SCWT.

While the present invention has been particularly shown and described with reference to exemplary embodiments thereof, it will be understood by those of ordinary skill in the art that various changes in form and details may be made therein without departing from the spirit and scope of the present invention. All material types provided herein to describe various dimensions, doping concentrations, and different semiconducting or insulating layers are for illustrative purposes only and not intended to be limiting. For example, the doping polarity of various silicon regions in the embodiments described herein may be reversed to obtain the opposite polarity type device of the particular embodiment. For these and other reasons, therefore, the above description should not be taken as limiting the scope of the invention, which is defined by the appended claims.

1. An insulated gate bipolar transistor (IGBT) comprising:
a collector region of a first conductivity type;
a first silicon region of a second conductivity type extending over the collector region;
a plurality of pillars of first and second conductivity types arranged in an alternating manner over the first silicon region, a bottom surface of each pillar of first conductivity type being vertically spaced from a top surface of the collector region; and
a plurality of well regions of the first conductivity type, each extending over and being in electrical contact with one of the pillars of the first conductivity type; and
a plurality of gate electrodes each extending over a portion of a corresponding well region, each gate electrode being insulated from its underlying regions by a gate dielectric layer,
wherein physical dimensions of each of the first and second conductivity type pillars and doping concentration of charge carriers in each of the first and second conductivity type pillars are selected so as to create a charge imbalance between a net charge in each pillar of first conductivity and a net charge in its adjacent pillar of the second conductivity type.

2. The IGBT of claim 1 wherein each of the pillars of the first conductivity type has a higher net charge than that of each of the pillars of the second conductivity type such that a charge imbalance in the range of 5-25% is obtained.

3. The IGBT of claim 1 wherein when the IGBT is switched off, minority carriers are removed through the pillars of the first conductivity type.

4. The IGBT of claim 1 further comprising a field stop layer of the second conductivity type extending between the first silicon region and the collector region, wherein the field stop layer has a doping concentration and thickness so as to prevent a depletion layer formed during IGBT operation from spreading to collector region.

5. The IGBT of claim 1 further comprising a field stop layer of the second conductivity type extending between the first silicon region and the collector region, wherein the field stop layer has a higher doping concentration than a doping concentration of the first silicon region.

6. The IGBT of claim 1 further comprising a source region of the second conductivity type formed in each well region so as to form a channel region in each well region, each gate electrode extending over at least the channel region in each well region.

7. The IGBT of claim 1 wherein a doping concentration in each of the pillars of first conductivity type is graded with the doping concentration along an upper portion of each of the pillars of the fist conductivity type being higher than the doping concentration along its bottom.

8. The IGBT of claim 1 wherein a doping concentration in each of the pillars of second conductivity type is graded with the doping concentration along an upper portion of each of the pillars of the second conductivity type being lower than the doping concentration along its bottom.

9. The IGBT of claim 1 wherein the pillars of the first conductivity type are configured as concentric rings.

10. The IGBT of claim 9 wherein the plurality of gate electrodes are configured as concentric rings.

11. The IGBT of claim 9 wherein the plurality of gate electrodes are stripe shaped.

12. The IGBT of claim 1 wherein the pillars of the first conductivity type are stripe shaped.

13. The IGBT of claim 12 wherein the plurality of gate electrodes are stripe shaped and extend parallel to the stripe shaped plurality of pillars of the first conductivity type.

14. The IGBT of claim 12 wherein the plurality of gate electrodes are stripe shaped and extend perpendicular to the stripe shaped pillars of the first conductivity type.

15. An insulated gate bipolar transistor (IGBT) comprising:
a collector region of a first conductivity type;
a first silicon region of a second conductivity type extending over the collector region;
a plurality of pillars of first and second conductivity types arranged in an alternating manner over the first silicon region, a bottom surface of each pillar of first conductivity type being vertically spaced from a top surface of the collector region; and
a well region of the first conductivity type extending over and being in electrical contact with the plurality of pillars of first and second conductivity types; and
a plurality of gate trenches each extending through the well region and terminating within one of the pillars of second conductivity type, each gate trench comprising a gate electrode therein,
wherein physical dimensions of each of the first and second conductivity type pillars and doping concentration of charge carriers in each of the first and second conductivity type pillars are selected so as to create a charge imbalance between a net charge in each pillar of first conductivity and a net charge in its adjacent pillar of the second conductivity type.

16. The IGBT of claim 15 wherein each of the pillars of the first conductivity type has a higher net charge than that of each of the pillars of the second conductivity type such that a charge imbalance in the range of 5-25% is obtained.

17. The IGBT of claim 15 wherein when the IGBT is switched off, minority carriers are removed through the pillars of the first conductivity type.

18. The IGBT of claim 15 further comprising a field stop layer of the second conductivity type extending between the first silicon region and the collector region, wherein the field stop layer has a doping concentration and thickness so as to prevent a depletion layer formed during IGBT operation from spreading to collector region.

19. The IGBT of claim 15 further comprising a field stop layer of the second conductivity type extending between the first silicon region and the collector region, wherein the field stop layer has a higher doping concentration than a doping concentration of the first silicon region.

20. The IGBT of claim 15 further comprising a plurality of source regions of the second conductivity type formed in the well region adjacent the plurality of gate trenches.

21. The IGBT of claim 15 wherein a doping concentration in each of the pillars of first conductivity type is graded with the doping concentration along an upper portion of each of the pillars of the fist conductivity type being higher than the doping concentration along its bottom.

22. The IGBT of claim 15 wherein a doping concentration in each of the pillars of second conductivity type is graded with the doping concentration along an upper portion of each of the pillars of the second conductivity type being lower than the doping concentration along its bottom.

23. The IGBT of claim 15 wherein the pillars of the first conductivity type are configured as concentric rings.

24. The IGBT of claim 23 wherein the plurality of gate electrodes are configured as concentric rings.

25. The IGBT of claim 23 wherein the plurality of gate electrodes are stripe shaped.

26. The IGBT of claim 15 wherein the pillars of the first conductivity type are stripe shaped.

27. The IGBT of claim 26 wherein the plurality of gate electrodes are stripe shaped and extend parallel to the stripe shaped pillars of the first conductivity type.

28. The IGBT of claim 26 wherein the plurality of gate electrodes are stripe shaped and extend perpendicular to the stripe shaped plurality of pillars of the first conductivity type.

29-59. (canceled)
